(19) United States
(12) Patent Application Publication
(10) Pub. No.: US 2026/0344325 A1
(43) Pub. Date: Oct. 29, 2026

(54) LIGHT ABSORPTION MEASUREMENT FOR CLOSED-LOOP PROCESS CONTROL

(71) Applicant: Applied Materials, Inc., Santa Clara, CA (US)

(72) Inventors: ABDULLAH ZAFAR, Santa Clara, CA (US); YIFAN HE, Mountain View, CA (US); TIMOTHY CHEN, Los Altos, CA (US); KELVIN CHAN, San Ramon, CA (US); DAVID BENJAMINSON, Campbell, CA (US); JINGCHUN ZHANG, San Jose, CA (US)

(21) Appl. No.: 19/189,115

(22) Filed: Apr. 24, 2025

(51) Int. Cl. H10P 72/00; C23C 16/52; G01N 21/3504; G01N 21/39

(52) U.S. Cl. CPC H10P 72/0402; C23C 16/52; G01N 21/3504; G01N 21/39

(57) ABSTRACT

Embodiments described herein relate to an apparatus includes a chamber, an optical input for the chamber, an optical output for the chamber, and an optical absorption sensor system coupled to the chamber. In an embodiment, the optical absorption sensor system includes a light source, an optical sensor, and a controller communicatively coupled to the optical sensor.

### BACKGROUND

### 1) Field

Embodiments relate to the field of semiconductor manufacturing and, in particular, systems and methods for implementing light absorption measurements for closed-loop process control.

### 2) Description of Related Art

In semiconductor manufacturing process, such as deposition or etching processes, the concentration of process-relevant species (e.g., radicals, molecules, etc.) is estimated by monitoring input gasses into the chamber and/or the exhaust from the chamber. For example, a mass flow controller (MFC) or valve position may be used to estimate the amount of gas that is flowing into the chamber. While this can provide some information about the system, the measurement of the inputs to the system does not dictate what is happening at the wafer-level. In some instances, the inputs to the chamber may be stable but the process may actually be drifting.

Since existing processes do not allow for analysis of the wafer-level conditions of the process, process control typically relies on periodic metrology of dummy wafers. For example, a dummy substrate is run at desired intervals, and the dummy substrate is then measured using metrology. If the metrology results are out of specification, the process may be adjusted to be brought back into the desired target range.

### SUMMARY

Embodiments described herein relate to an apparatus includes a chamber, an optical input for the chamber, an optical output for the chamber, and an optical absorption sensor system coupled to the chamber. In an embodiment, the optical absorption sensor system includes a light source, an optical sensor, and a controller communicatively coupled to the optical sensor.

Embodiments described herein relate to a method that includes propagating a laser beam through a volume of a chamber, and determining a concentration of a species in the chamber by detecting a change in an intensity of the laser beam. In an embodiment, the method further includes changing a flow gas into the chamber in response to the concentration of the species in the chamber.

Embodiments described herein relate to a system that includes a processing tool. In an embodiment, the processing tool includes a chamber, a gas source, and a gas flow controller configured to control a flow of gas from the gas source into the chamber. In an embodiment, the system further includes a feedback control system configured to control the gas flow controller. In an embodiment, the feedback control system includes a light source, an optical sensor, and a controller. In an embodiment, the controller is configured to control a state of the gas flow controller.

### BRIEF DESCRIPTION OF THE DRAWINGS

FIG. 1 is a graph that depicts a pulse pattern of a deposition chamber and a corresponding concentration of a species within the chamber, in accordance with an embodiment.

FIG. 2 is a cross-sectional illustration of a chamber with an optical input and an optical output for implementing laser absorption spectroscopy, in accordance with an embodiment.

FIG. 3A is a schematic illustration of an absorption spectroscopy system that is coupled to a chamber, in accordance with an embodiment.

FIG. 3B is a schematic illustration of an absorption spectroscopy system with a pair of light sources that is coupled to a chamber, in accordance with an embodiment.

FIG. 4 is a schematic illustration of the feedback control system that uses laser absorption spectroscopy to control a flow of gas into a processing chamber, in accordance with an embodiment.

FIG. 5 is a flow diagram of a process for controlling gas flow into a chamber as a result of a laser absorption spectroscopy, in accordance with an embodiment.

FIG. 6 is a flow diagram of a process for calculating a species concentration in a chamber with a laser absorption spectroscopy process, in accordance with an embodiment.

FIG. 7 illustrates a block diagram of an exemplary computer system that may be used in conjunction with a processing tool, in accordance with an embodiment.

### DETAILED DESCRIPTION

Embodiments described herein include systems and methods for implementing light absorption measurements for closed-loop process control. In the following description numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, existing process control for semiconductor processing is limited. For example, the ability to find the wafer-level concentration of species within the chamber may be limited to the knowledge of the inputs into the system. Other solutions for determining species concentration within a chamber may include optical emission spectroscopy (OES). OES measures the emission of a plasma in order to determine the presence of species within the chamber. However, OES is generally qualitative. For example, the intensity of the emission line used for the OES depends significantly on a number of other variables such as neutral species density, neutral species temperature, electron density, electron temperature, electric field strength, magnetic field strength, etc. As such, it is not possible to determine an absolute measure of the concentration of the species within the chamber without other techniques such as a collisional radiative model and/or actinometry. Furthermore, in locations without plasma present, OES measurements are not possible. This leads to issues with process control and makes matching between chambers much more difficult.

Accordingly, embodiments disclosed herein include the use of laser absorption spectroscopy (LAS) to determine a species concentration within the chamber. In an embodiment, the LAS process may include a laser that passes through the chamber proximate to the surface of the substrate. The use of LAS allows for a more direct measurement of the concentration since the absorption of the laser is a function of the species concentration. Further, the wavelength of the light source may be selected to specifically absorb the species of interest. In some embodiments, the accuracy of the species concentration may be increased through the use of a wavelength sweep and/or a sinusoidal modulation to the laser.

In an embodiment, light is passed directly above the substrate and the light is absorbed only by the species of interest. The species of interest may be a process gas, a radical, or an etch byproduct. In an embodiment, the light source may be a thermal light source (e.g., an infrared (IR) light source), a light emitting diode (LED), or a laser. In an embodiment, the signal from this sensor may be used to control the chamber in a manner that maintains the level of radicals, species, and/or byproducts at a consistent level over time. For example, the sensor may be used to generate control signals that are used to change the flow of gas into the chamber.

Embodiments disclosed herein also allow for absolute measurement of the concentration of the species within the chamber. Since an absolute measurement is made, two different chambers may be matched. Matching chambers allows for improved processing uniformity across a fabrication facility.

Since the actual species concentration at the substrate surface can be monitored and controlled with the in-situ monitoring, embodiments are able to significantly reduce process drift. Since the process drift is reduced and the process is stabilized, the need for dummy wafers is reduced and/or eliminated. As such, the cost of the process may be decreased and/or the throughput may be increased.

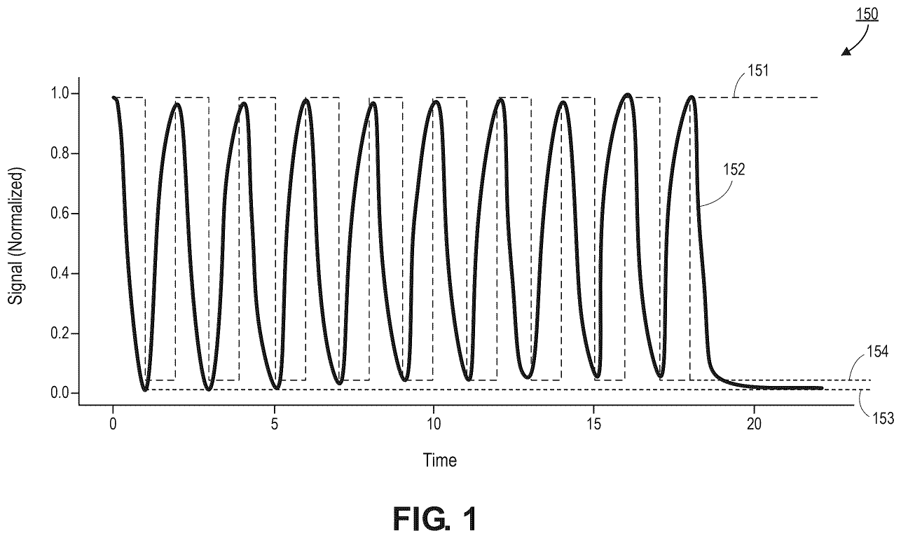

Referring now to FIG. 1, a graph 150 that depicts a concentration of a species in a chamber and the pulse pattern of gas into the chamber is shown, in accordance with an embodiment. In an embodiment, the line 151 is the pulse pattern, with 1.0 representing a closed valve and 0.0 representing an open valve. In an embodiment, the concentration 152 is represented as a normalized signal intensity with 1.0 being an indication of there being a maximum concentration of the species and 0.0 representing a low concentration of the species.

As shown, the concentration 152 reduces as the valve is closed, and the concentration increases when the valve is opened. In some instances, measurement of the state of the valve (e.g., whether the valve is open or the valve is closed) is used in order to estimate the concentration of the species within the chamber. However, as indicated by the concentration levels over time, the process may drift even when the pulsing remains constant. For example, the valleys of the concentration of species may reach approximately 0.0 at the beginning of the process (i.e., about to line 153), but the concentration may only reach the concentration level at about line 154 later in the process. This may occur due to the species not being totally evacuated during the purge cycle (e.g., when the valve is closed). However, monitoring only the state of the valves would not identify such residual species during the process. This can lead to processing non-uniformities and make it difficult to match chambers within a processing facility (e.g., a fab).

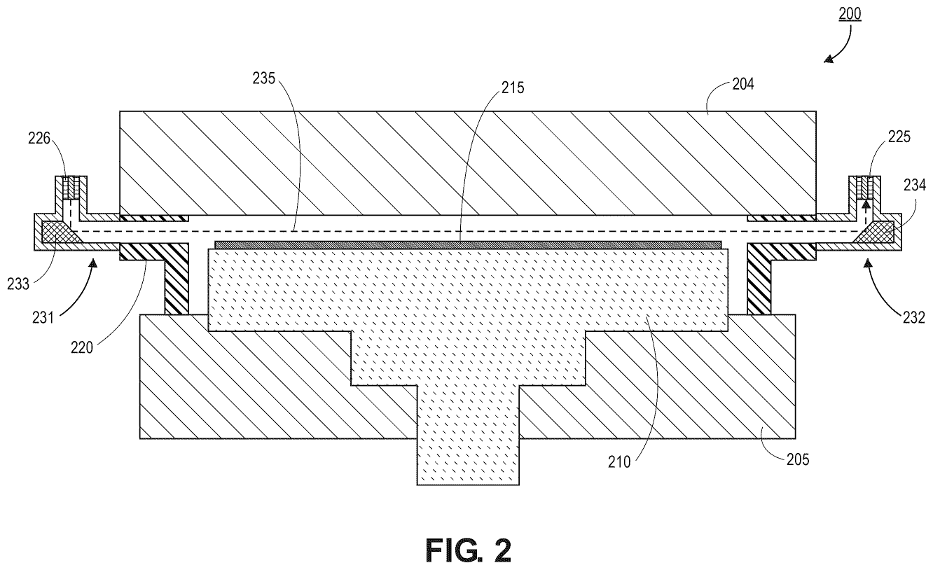

Referring now to FIG. 2, a cross-sectional illustration of a chamber 200 is shown, in accordance with an embodiment. In an embodiment, the chamber 200 may be any type of processing chamber used in semiconductor manufacturing environments. In some embodiments, the chamber 200 may be a deposition chamber (e.g., a chemical vapor deposition (CVD) chamber or an atomic layer deposition (ALD) chamber), an etching chamber, a plasma treatment chamber, or the like.

As shown, the chamber 200 may comprise a chamber enclosure 204, 205. The enclosure 204 may be a lid, an electrode, or the like. For example, the enclosure 204 may comprise a ceramic material, a semiconductor material, a metallic material, or the like. The enclosure 205 may be a metallic body or wall around an interior volume of the chamber. In other embodiments, the enclosure 205 may be a chamber liner, a process kit, or the like that surrounds a pedestal 210. In an embodiment, the pedestal 210 may support a substrate 215 within the chamber 200. The pedestal 210 may comprise an electrostatic chuck (ESC) or the like in order to secure the substrate 215 to the pedestal 210.

In an embodiment, a spacer 220 may be provided between the enclosure 204 and the enclosure 205. The spacer 220 may comprise a portion of a wall of the chamber 200 in some embodiments. As shown, the spacer 220 may accommodate an optical input 231 and an optical output 232 that are on opposite sides of the chamber 200. In an embodiment, the optical input 231 and the optical output 232 may allow for an optical signal (e.g., light 235) to pass through the interior of the chamber 200. In an embodiment, the light 235 may be a laser beam with any suitable wavelength, an IR beam, an optical beam, or the like. In an embodiment, the optical input 231 may comprise a collimator 226 and a mirror 233. The collimator 226 may be optically coupled to an optical fiber (not shown) that allows for the light 235 to be propagated from a light source (not shown) to the chamber 200. Similarly, the optical output 232 may comprise a collimator 225 and a mirror 234. The collimator 225 may be optically coupled to a second optical fiber (not shown) that allows for the light 235 to be propagated from the chamber to an optical detector (not shown) in order to determine an amount of a desired species within the chamber 200.

In an embodiment, the optical path between the optical input 231 and the optical output 232 may be provided across the volume of the chamber 200 proximate to a surface of the substrate 215. As such, the measurement of the species within the chamber may be determined at substantially the substrate level. This allows for improved process control since the species at the surface of the substrate 215 are the species that are impacting the processing of the substrate 215. Accordingly, a more accurate picture of the processing outcomes on the substrate may be provided.

In the illustrated embodiment, a simplified and generic processing chamber is described. However, it is to be appreciated that any processing chamber configuration may be used, in accordance with embodiments disclosed herein. Further, while the optical input 231 and the optical output 232 are shown as being formed through the spacer 220, embodiments may also include forming the optical input 231 and/or optical output 232 through any wall or other outer surface of the chamber 200. In yet another embodiment, the optical input 231 and the optical output 232 may be a single structure, and a mirror within the chamber 200 may reflect the light 235 that enters the chamber 200 through an optical port back out of the same optical port.

As can be appreciated from FIG. 2, embodiments allow for an optical signal to pass through the chamber 200 in order to implement one or more different types of optical sensing of the chamber interior. In a particular embodiment, the optical sensing may include an absorption spectroscopy process. In such an embodiment, the light source may be tuned to a wavelength that is preferentially absorbed by the species of interest. As such, a determination of the percentage of the light 235 that is absorbed as it passes through the chamber 200 interior can be used to calculate the concentration of the species of interest.

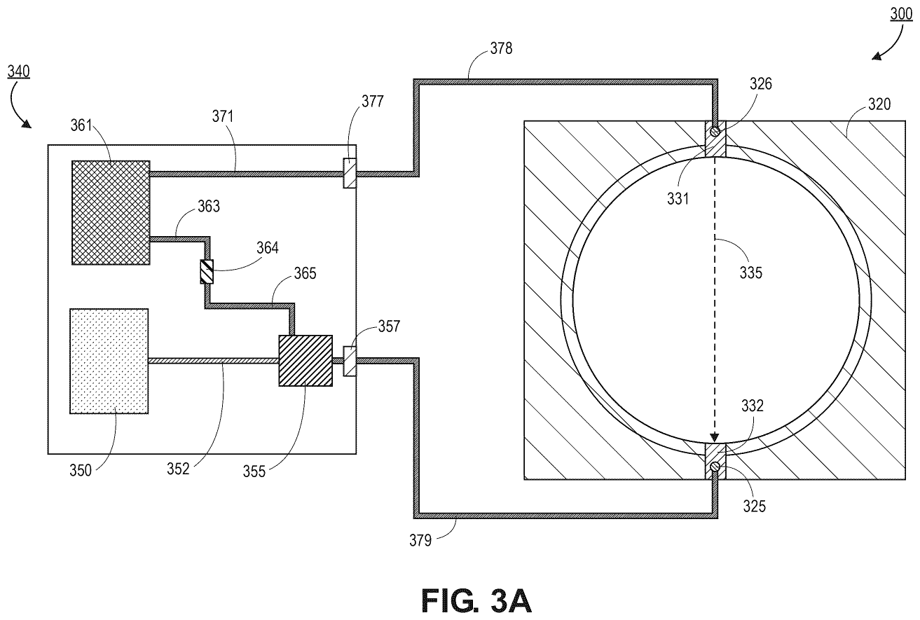

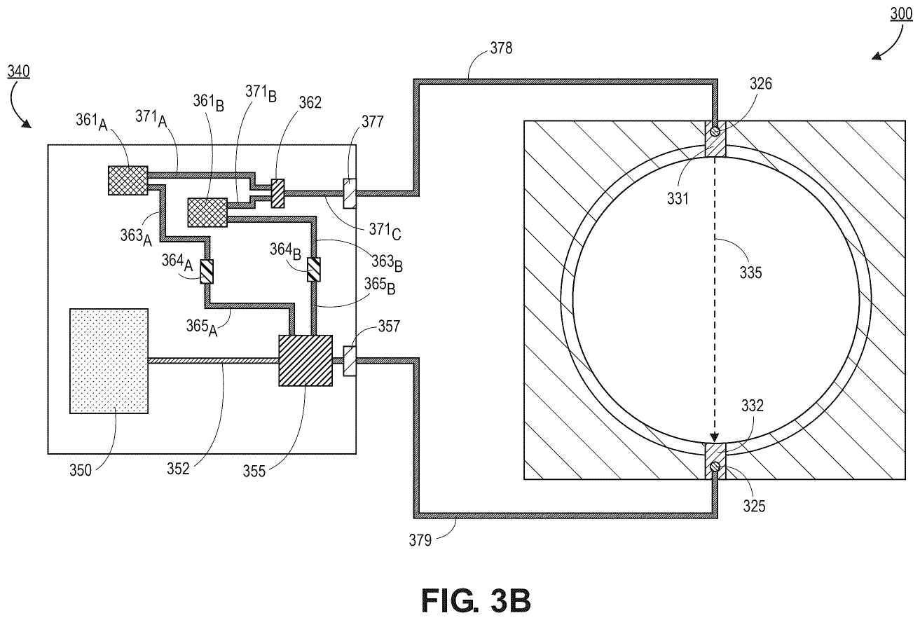

Referring now to FIG. 3A, a plan view schematic illustration of a portion of a chamber 300 the is optically coupled to a sensor system 340 is shown, in accordance with an embodiment. In an embodiment, the chamber 300 may be similar to the chamber 200 described in greater detail herein. In an embodiment, the spacer 320 of the chamber 300 is shown. The spacer 320 may comprise an optical input 331 with a collimator 326 and an optical output 332 with a collimator 325. In an embodiment, light 335 may propagate across an interior of the chamber 300 from the optical input 331 to the optical output 332.

In an embodiment, the sensor system 340 is shown as being on a single board. Other embodiments may include implementing the sensor system 340 on one or more different boards, enclosures, or the like. In an embodiment, the sensor system 340 may comprise a light source 361. The light source 361 may be any type of light source 361 that is capable of generating light at a desired wavelength to implement absorption spectroscopy. For example, the light source 361 may comprise a laser, an IR light source, an LED, or the like. The wavelength of the light source 361 may be a deep ultraviolet (DUV) wavelength to an IR wavelength. In some embodiments, the wavelength of the light source 361 may be tuned to absorb species (e.g., radicals, molecules, neutrals, etc.), such as one or more of pentakis(dimethylamino) tantalum (PDMAT) molecules, metastable He, HF molecules, F (+H₂) radicals, F₂ molecules, HCl molecules, Cl (+H₂) radicals, N radicals, O radicals, OH radicals, H₂O molecules, CO molecules, CO₂ molecules, NH₃ molecules, SiF₄ molecules, NF₂ radicals, NH₂ radicals, SiH radicals, dimethylamine molecules, diborane molecules, IRIS, DORIS, CH molecules, and/or the like.

In an embodiment, the light source 361 may be optically coupled to the optical input 331 of the chamber 300 by one or more optical cables. For example, an optical cable 371 may optically couple the light source 361 to an on board connector 377, and an additional optical cable 378 may optically couple the on board connector 377 to the optical input 331 of the chamber 300.

In an embodiment, the optical output 332 of the chamber 300 may be optically coupled to the sensor system 340 through one or more optical cables. For example, an optical cable 379 optically couples the optical output 332 to an on board connector 357. The on board connector 357 may be optically coupled to an optical sensor 355, such as a photodiode or the like, by an additional optical cable in some embodiments. In an embodiment, the optical sensor 355 is configured to determine an intensity of the light 335 after it has passed through the chamber 300 in order to determine an amount of the light 335 that has been absorbed by the target species within the chamber 300.

In order to provide accurate quantitative values of the species within the chamber 300, the sensor system 340 may also comprise a reference cell 364. In an embodiment, the reference cell 364 may comprise a known quantity of the species of interest. The reference cell 364 may be optically coupled between the light source 361 and the optical sensor 355. Since the light source 361 and the optical sensor 355 for the reference cell 364 are the same as the ones used for measuring species in the chamber 300, an accurate measurement may be made after the sensor system 340 is calibrated by the reference cell 364.

In an embodiment, the sensor system 340 may also comprise a controller 350 that is communicatively coupled to the optical sensor 355 by an interconnect 352 (such as a data cable, an electrical trace, or the like). In an embodiment, the controller 350 may comprise an analog to digital converter that is configured to turn the measured light signal from the optical sensor 355 into a digital signal that can be used to control the chamber 300. For example, the light signal that is related to species concentration may be used as feedback information that is used to control the delivery of one or more gases into the chamber, as will be described in greater detail herein.

Referring now to FIG. 3B, an illustration of a chamber 300 is shown, in accordance with an additional embodiment. In an embodiment, the chamber 300 in FIG. 3B is similar to the chamber 300 in FIG. 3A, with the exception of the sensor system 340 including a plurality of light sources 361. For example, the sensor system 340 may comprise a first light source 361_{A} and a second light source 361_{B}. The first light source 361_{A} and the second light source 361_{B} may emit light at different wavelengths. As such, the light is configured to measure different species within the same chamber 300. In an embodiment, the light sources 361_{A} and 361_{B} may be optically coupled to an optical combiner 362 by optical fibers 371_{A} and 371_{B}, and the optical combiner 362 may be optically coupled to the on board connector 377 by an optical fiber 371_{C}. At this point, light with both wavelengths are provided on the optical path to the chamber 300. In an embodiment, light 335 with both wavelengths passes through the chamber 300 and is delivered to the optical sensor 355. Accordingly, the absorption of two different species is determined through the use of a single optical input 331 and a single optical output 332.

Similar to the embodiment described above with respect to FIG. 3A, a reference cell 364_{A} may be provided for the first light source 361_{A}, and a reference cell 364_{B} may be provided for the second light source 361_{B}. The reference cells 364 may be optically coupled between the light sources 361 and the optical sensor 355 by optical cables 363_{A}, 363_{B}, and 365_{A}, 365_{B}. In this way accurate quantitative values of the concentration of two species within the chamber 300 may be obtained with a single sensor system 340.

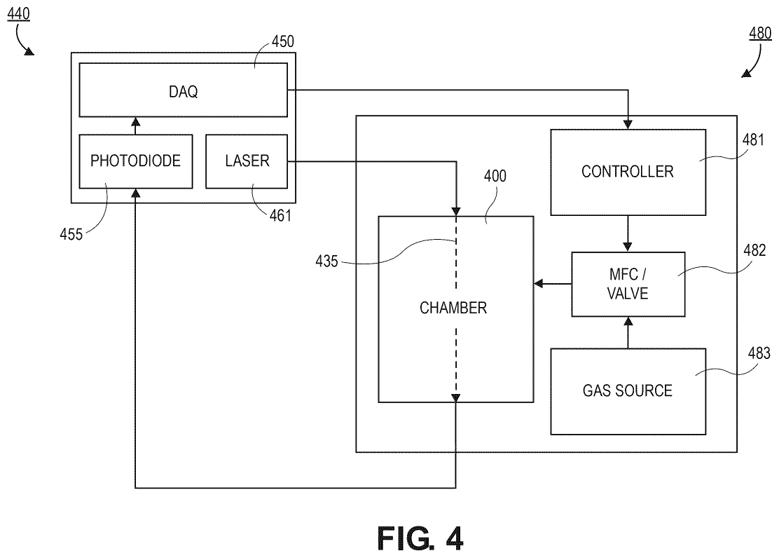

Referring now to FIG. 4, a schematic illustration of a control system for a processing tool 480 is shown, in accordance with an embodiment. In an embodiment, the processing tool 480 may comprise a chamber 400. The chamber 400 may be similar to any of the chambers described in greater detail herein. For example, the chamber 400 may comprise a deposition chamber, an etching chamber, a treatment chamber, or the like. In an embodiment, the processing tool 480 may further comprise a gas source 483 that supplies gas into the chamber 400. The gas source 483 may comprise one or more different gasses (e.g., precursors, inert gasses, etc.). In an embodiment, the flow of gas into the chamber 400 may be controlled by a gas controller 482. The gas controller 482 may comprise an MFC, a valve, and/or the like. In an embodiment, a state of the gas controller 482 may be dictated by a controller 481. The controller 481 may send control signals to the gas controller 482 that increases and/or decreases a flow of gas into the chamber 400.

In an embodiment, a sensor system 440 may be coupled to the processing tool 480. The sensor system 440 may be similar to any of the sensor systems described in greater detail herein. For example, the sensor system 440 may include a light source 461 (e.g., a laser) that is optically coupled to the chamber 400 in order to propagate light 435 through an interior of the chamber 400. The light 435 is then delivered to an optical sensor 455 (e.g., a photodiode) to determine an amount of absorption of the light 435 by species within the chamber 400.

In an embodiment, the optical sensor 455 is communicatively coupled to a controller 450, such as an analog to digital converter data acquisition system (DAQ). In an embodiment, the controller 450 of the sensor system 440 may be communicatively coupled to the controller 481 of the processing tool 480. When the DAQ controller 450 indicates that the concentration of the species within the chamber is outside of a predetermined range or specification, the controller 481 may be used to alter the state of the gas controller 482 in order to bring the concentration of species within the chamber 400 back to within the desired range or specification. That is, the sensor system 440 may use species concentration information as a feedback input in order to improve control of processing outcomes within the processing tool 480.

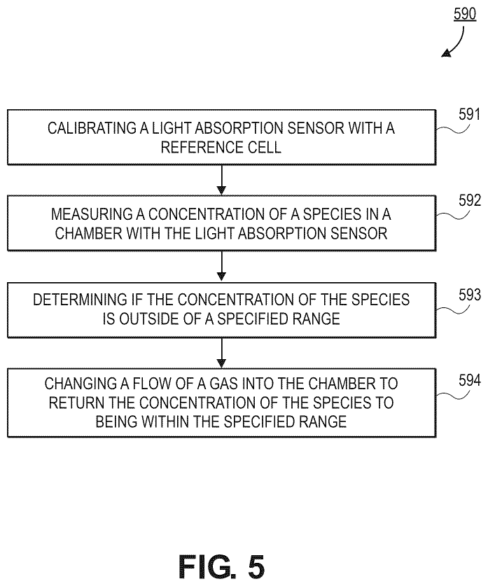

Referring now to FIG. 5, a process flow diagram that depicts a process 590 for controlling the processing of a substrate within a chamber is shown, in accordance with an embodiment. In an embodiment, the chamber may include a system for implementing absorption spectroscopy that enables accurate determination of species concentrations within the chamber. This concentration information may then be used as a feedback input in order to prevent process drift or the like.

In an embodiment, the process 590 may begin with operation 591, which comprises calibrating a light absorption sensor with a reference cell. In an embodiment, the reference cell may comprise a known quantity of the species of interest. The light source that will be used for the measurement emits light that is propagated through the reference cell in order to calibrate the light source and/or the optical sensor.

In an embodiment, the process 590 may continue with operation 592, which comprises measuring a concentration of the species in a chamber with the light absorption sensor. In an embodiment, the light absorption sensor may be similar to any of the light absorption sensors described in greater detail herein. For example, the output of the light source may be routed through an interior of the chamber proximate to a surface of the substrate. In an embodiment, the measurement of the concentration of the species may be made through any suitable absorption spectroscopy process. In an embodiment, a fixed wavelength light is used to measure the absorption. In other embodiments, the wavelength of the light source is tunable between a first wavelength and a second wavelength. In such an embodiment, the light source may scan (or sweep) between the first wavelength and the second wavelength in order to improve the accuracy of the absorption reading. In some embodiments, the difference between the second wavelength and the first wavelength may be approximately 5 nm or less or approximately 1 nm or less. In yet another embodiment, a sinusoidal modulation may be applied to the wavelength sweep to even further increase an accuracy of the absorption reading.

In an embodiment, the process 590 may continue with operation 593, which comprises determining if the concentration of the species is outside of a specified range. In an embodiment, the determination may be made by a processor and/or controller that is communicatively coupled to the light absorption sensor. In an embodiment, the specified range may include an upper and/or lower bound on the species concentration that ensures uniform and high yielding processing outcomes on a substrate being processing in the chamber.

In an embodiment, the process 590 may continue with operation 594, which comprises changing a flow of a gas into the chamber to return the concentration of the species to being within the specified range. In an embodiment, the flow of gas into the chamber may be modified by changing a state of a gas control system, such as an MFC, a valve, and/or the like. In an embodiment, the change may include changing a position of the valve to allow more or less gas to flow into the chamber, changing a pulse duration of a valve, changing a pulse frequency of a valve, changing a temperature, changing a pressure, and/or the like. In an embodiment, the light absorption sensor may be communicatively coupled to a controller of the gas control system. In this way, feedback information from the light absorption sensor may be used in order to tightly control the processing conditions within the chamber. Accordingly, chamber drift is minimized.

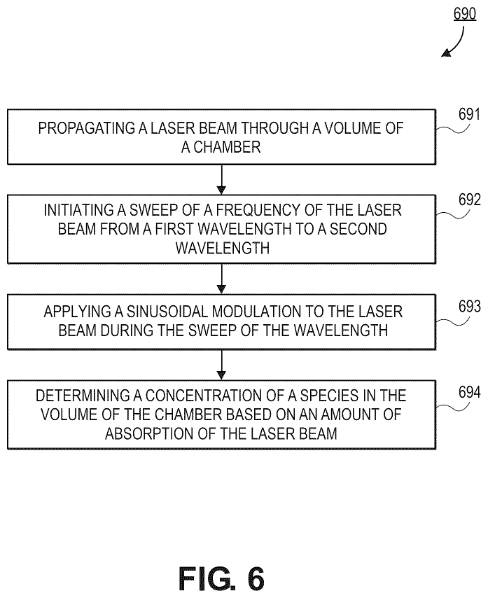

Referring now to FIG. 6, a flow diagram that depicts a process 690 for implementing light absorption sensing to determine a concentration of a species within a chamber is shown, in accordance with an embodiment. In an embodiment, the process 690 may begin with operation 691, which comprises propagating a laser beam through a volume of a chamber. While described as a laser beam, other light sources may be used similar to other embodiments described herein.

In an embodiment, the process 690 may continue with operation 692, which comprises initiating a sweep of a wavelength of the laser beam from a first wavelength to a second wavelength. In an embodiment, the sweep may include a change in the wavelength of the laser beam of approximately 5 nm or less or approximately 1 nm or less.

In an embodiment, the process 690 may continue with operation 693, which comprises applying a sinusoidal modulation to the laser beam during the sweep of the wavelength. In an embodiment, the inclusion of a sinusoidal modulation may further increase an accuracy of the absorption readings determine by the system.

In an embodiment, the process 690 may continue with operation 694, which comprises determining a concentration of a species in the volume of the chamber based on an amount of absorption of the laser beam. In an embodiment, the percentage off the absorption of the laser beam may be correlated to the desired concentration of the targeted species. In some embodiments, the accurate quantitative measurement of the species concentration may allow for improved process control within the chamber. Additionally, accurate quantitative measurements of the species concentration may allow for improved chamber matching throughout a fab in a high volume manufacturing (HVM) environment.

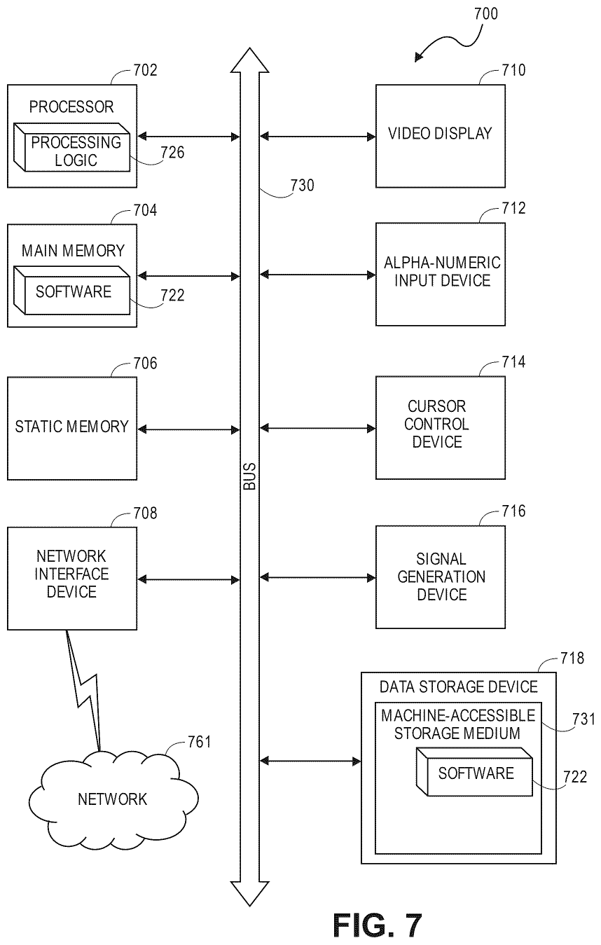

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 761 via the system network interface device 708. In an embodiment, the network interface device 708 may operate using RF coupling, optical coupling, acoustic coupling, or inductive coupling.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a chamber;
an optical input for the chamber;
an optical output for the chamber; and
an optical absorption sensor system coupled to the chamber, wherein the optical absorption sensor system comprises:
a light source optically coupled to the optical input;
an optical sensor optically coupled to the optical output; and
a controller communicatively coupled to the optical sensor.

2. The apparatus of claim 1, wherein the light source comprises:
a laser, a light emitting diode (LED), or an infrared (IR) light source.

3. The apparatus of claim 1, further comprising:
a gas source fluidly coupled to the chamber; and
a flow controller configured to control a flow of gas from the gas source to the flow controller.

4. The apparatus of claim 3, wherein the controller is communicatively coupled to the flow controller, and wherein the controller is configured to control a state of the flow controller in order to change a flow rate of gas into the chamber.

5. The apparatus of claim 3, wherein the flow controller comprises a mass flow controller (MFC).

6. The apparatus of claim 3, wherein the flow controller comprises a valve.

7. The apparatus of claim 1, wherein the optical input comprises a first mirror collimator, and wherein the optical output comprises a second mirror collimator.

8. The apparatus of claim 1, wherein the optical absorption sensor system comprises a laser absorption spectroscopy sensor.

9. The apparatus of claim 8, wherein the laser absorption spectroscopy sensor comprises wavelength modulation.

10. The apparatus of claim 9, wherein the wavelength modulation further comprises a sinusoidal modulation.

11. A method, comprising:
propagating a laser beam through a volume of a chamber;
determining a concentration of a species in the chamber by detecting a change in an intensity of the laser beam; and
changing a flow of gas into the chamber in response to the concentration of the species in the chamber.

12. The method of claim 11, further comprising:
initiating a sweep of a wavelength of the laser beam from a first wavelength to a second wavelength.

13. The method of claim 12, further comprising:
applying a sinusoidal modulation to the laser beam during the sweep of the wavelength.

14. The method of claim 12, wherein the first wavelength is within 5 nm of the second wavelength.

15. The method of claim 11, further comprising:
calibrating an intensity of the laser beam with a reference cell.

16. The method of claim 11, wherein the species comprises a radical or a molecule.

17. A system comprising:
a processing tool, wherein the processing tool comprises:
a chamber;
a gas source; and
a gas flow controller configured to control a flow of gas from the gas source into the chamber; and
a feedback control system configured to control the gas flow controller, wherein the feedback control system comprises:
a light source;
an optical sensor; and
a controller, wherein the controller is configured to control a state of the gas flow controller.

18. The system of claim 17, wherein the gas flow controller comprises a mass flow controller or a valve.

19. The system of claim 17, wherein the light source comprises a laser.

20. The system of claim 17, wherein the processing tool is a deposition tool or an etching tool.
